(19) United States
(12) Patent Application Publication
(10) Pub. No.: US 2026/0229283 A1
(43) Pub. Date: Aug. 6, 2026

(54) STATIC RANDOM ACCESS MEMORY DEVICE

(71) Applicant: NATIONAL CHUNG CHENG UNIVERSITY, CHIA-YI (TW)

(72) Inventors: JINN-SHYAN WANG, CHIA-YI (TW); DENG-CHUN YANG, NEW TAIPEI CITY (TW)

(21) Appl. No.: 19/175,292

(22) Filed: Apr. 10, 2025

(30) Foreign Application Priority Data
Feb. 4, 2025 (TW) 114104023

(51) Int. Cl. G11C 11/418; G11C 5/06; G11C 5/14

(52) U.S. Cl. CPC G11C 11/418; G11C 5/063; G11C 5/14

(57) ABSTRACT

A static random access memory device includes at least one word line, a first bit line, a second bit line, a power supply line, a first ground line, a second ground line, and a static random access memory cell. The power supply line is parallel to the first bit line, the second bit line, the first ground line, and the second ground line and is perpendicular to the word line. The static random access memory cell includes a first inverter, a second inverter, a first pass transistor, and a second pass transistor. The first inverter and the second inverter are cross-coupled and respectively coupled to the first pass transistor and the second pass transistor. The static random access memory cell is coupled to the power supply line, the first ground line, the second ground line, the word line, the first bit line, and the second bit line.

### BACKGROUND OF THE INVENTION

This application claims priority for the TW Application No. 114104023 filed on 4 February 2025, the content of which is incorporated by reference in its entirely.

### FIELD OF THE INVENTION

The present invention relates to a memory device, particularly to a static random access memory device.

### DESCRIPTION OF THE RELATED ART

The semiconductor memories, and more particularly the static random access memories (SRAM), are important building components in microelectronic systems, multi-processor chips or system-on-chips (SoC). An SRAM is typically arranged as an array of memory cells. Address decoding allows access to each cell for performing read or write functions. The conventional six-transistor CMOS SRAM cell includes two n-type pull-down transistors (NMOS) and two p-type pull-up transistors (PMOS) in a cross-coupled inverter configuration, with two additional NMOS pass-gate transistors added to make up a standard double-sided differential memory cell. The traditional six-transistor CMOS SRAM cell is usually abbreviated as a 6T CMOS SRAM cell, a 6T SRAM cell, a 6T bit-cell, a differential 6T cell, or simply a 6T cell.

The most conventional 6T SRAM bit cell, or called the standard 6T bit cell, has several interconnection ports, including a single power-supply line (VDD), a single ground line (GND), a single word line (WL), and complementary bit lines (BL and BLB). Constructing a memory cell array depends on the physical interconnection of the cells' ports. The physical interconnection ways for the ports in the most conventional 6T SRAM bit cell have two styles: (1) the VDD line runs in parallel with BL and BLB lines but is perpendicular to GND and WL lines, or (2) the VDD line runs in parallel with GND, BL and BLB lines but is perpendicular to the WL line. The SRAM can adopt style (2) for interconnection when considering the shrinking trend of contact windows when the SRAM is designed in advanced process technologies.

FIG. 1 is a schematic of a 2×2 SRAM cell array 10 with four standard 6T cells 100, 101, 110, and 111. In FIG. 1, the physical interconnection ways are in the styles: (1) the VDD line of the cell runs in parallel with BL and BLB lines of the cell but is perpendicular to GND and WL lines of the cell, and (2) the VDD line of each column of cells run in parallel with BL and BLB lines of each column of cells but are perpendicular to GND and WL lines of each row of cells. The upper row comprises two cells, 100 and 101, connecting to the same word line, WL0, and the lower row comprises two cells, 110 and 111, connecting to the other word line, WL1. In the typical layout design, the neighboring two cells in the same row, such as cells 100 and 101, are physically mirrored in the horizontal direction, and the neighboring two cells in the same column, such as cells 100 and 110, are physically mirrored in the vertical direction. Both rows' ground lines, RL0 and RL1, are connected to the system's ground node GND. In the physical layout design, word lines WL0 and WL1 and ground lines RL0 and RL1 run in the same direction, i.e., horizontally in this diagram. On the other hand, the power supply line of each column of cells, such as lines PWL0 and PWL1 in FIG. 1, runs in the vertical direction, the same as that of the bit lines BL and BLB.

To operate the SRAM in a supply voltage lower than the nominal voltage the foundry specifies, the SRAM needs add-on assist circuits to improve the stability of the accessed and non-accessed 6T cells. The SRAM can also use specially designed memory cells instead of the 6T cell, such as the Dual-Split-Control 6T cell (DSC 6T) or the Generic-Split-Control 6T cell (GSC 6T) along with the assist circuits for reliable read, write, and even power-saving operations. FIG. 2 shows the schematic of a GSC6T cell, with split word lines running in parallel with split ground lines. In FIG. 2, the physical interconnection ways are in the styles: (1) the VDD line of the cell runs in parallel with BL and BLB lines of the cell but is perpendicular to the RL and RL’ lines and the WL and WL’ lines of the cell, and (2) the VDD line of each column of cells run in parallel with BL and BLB lines of each column of cells but are perpendicular to RL and RL’ lines and WL and WL’ lines of each row of cells. FIG. 3 shows a schematic of a 2x2 low-voltage (LV) SRAM cell array 20 with four GSC 6T cells: 200, 201, 202, and 203. The cells are arranged in a mirrored fashion, whether in the horizontal and vertical directions. The upper row comprises two cells, 200 and 201, connecting to the same split word lines, WL and WL’, and the lower row comprises two cells, 202 and 203, connecting to the other split word lines, WL and WL’. The word line assist (WL-assist) circuits W generate all split word lines. Each row of cells has split ground lines, and the ground line assist (GND-assist) circuits R generate all split ground lines. The power-supply line assist (VCC-assist) circuits P generate all power supply lines, such as PWL and PWL’. The bit line assist circuits B generate all bit lines BL and BLB. To match with the assist circuits, word lines and ground lines run in the same direction, and the power supply lines and the bit lines run perpendicularly in the physical layout design.

The SRAM designer can replace the GSC6T cells in FIG. 3 with other cells, such as the 6T or DSC6T cells, along with corresponding assist circuits so that the SRAM can also operate in a supply voltage lower than the nominal supply voltage the foundry specifies. In the physical layout design, word lines and ground lines run in the same direction, and the power supply lines and the bit lines run perpendicularly.

It is well known that an SRAM has a design concern of bit-line-wise data dependency, implying that the reading speed depends on the stored data of a column of cells attached to the bit line. Bit-line-wise, or called column-wise data dependency, may limit the maximum number of cells attached to a column.

For the LV SRAM, such as the cell array shown in FIG. 3, besides the issue of column-wise data dependency, there is another design concern of word-line-wise or row-wise data dependency, implying that the reading speed also depends on the stored data of a row of cells. The synergy of column- and row-wise data dependencies deteriorates the reading speed and limits the maximum number of cells attached to a column and the maximum number of cells in one row. Take the single-ended reading scheme as an example; one sense amplifier (SA) is attached to each column's bit line, as shown in FIG. 4. FIG. 4 shows the exemplary current flows in the cell array when performing a read operation for the upper row of cells. In this example, the stored data of cells 200 and 201 differ. The current in the left column flows from the bit line through the cell 200 to the GND line RL and finally to the system's ground node GND, but the current in the right column does not flow to the GND line because the device Q4 of cell 201 is turned off. For a cell array with N cells in a row, the total current flowing to the GND line depends on the stored data pattern of the row. Note that due to parasitic resistance and capacitance associated with the GND line, the current flowing to the GND line induces voltage bumps and then causes different transient ground voltages of the cells in the row. Accordingly, the reading speed depends on the data pattern, and the reading speed of each column varies.

In addition to the values stored in the cells along the bit line direction (i.e., the column direction) of the general memory, the operating speed of the static random access memory is affected by the values stored in the cells along the word line direction (i.e., the row direction). The former is also called row-wise data dependency and the latter is also called column-wise data dependency. The coexistence of row-wise data dependency and column-wise data dependency will expand the range of variation of the operating speed, make the slowest operating speed very bad, and reduce memory reliability. This problem becomes worse when the supply voltage provided to the SRAM is reduced.

To overcome the abovementioned problems, the present invention provides a static random access memory device.

### SUMMARY OF THE INVENTION

The present invention provides a static random access memory device, which avoids row-wise data dependency. Compared with a conventional low-voltage (LV) SRAM with ground-line assist circuits, the invented static random access memory device reduces the range of variation of the operating speed, increases the slowest operating speed, improves the reliability and the competitiveness of low voltage static random access memory, and expands the application range.

In an embodiment of the present invention, a static random access memory device includes a plurality of word lines, a plurality of bit lines, a plurality of power supply lines, a plurality of ground lines, and a plurality of static random access memory cells. The word lines include at least one first word line. The bit lines include a first bit line, a second bit line, a third bit line, and a fourth bit line. The power supply lines include a first power supply line and a second power supply line. The ground lines include a first ground line, a second ground line, a third ground line, and a fourth ground line. The power supply lines run in a direction parallel to the bit lines and the ground lines but perpendicular to the word lines. The static random access memory cells include a first static random access memory cell and a second static random access memory cell. The first static random access memory cell includes a first inverter, a second inverter, a first pass transistor, and a second pass transistor. The first inverter and the second inverter are cross-coupled and coupled to the first power supply line. The first inverter is coupled to the first ground line. The second inverter is coupled to the second ground line. The first pass transistor is coupled to the first word line, the first bit line, the first power supply line, and the first inverter. The second pass transistor is coupled to the first word line, the second bit line, the first power supply line, and the second inverter. The second static random access memory cell includes a third inverter, a fourth inverter, a third pass transistor, and a fourth pass transistor. The third inverter and the fourth inverter are cross-coupled and coupled to the second power supply line. The third inverter is coupled to the third ground line. The fourth inverter is coupled to the fourth ground line. The third pass transistor is coupled to the first word line, the third bit line, the second power supply line, and the third inverter. The fourth pass transistor is coupled to the first word line, the fourth bit line, the second power supply line, and the fourth inverter.

To sum up, the static random access memory device arranges the power supply line that is parallel to the bit lines and the ground lines and perpendicular to the word lines to avoid row-wise data dependency. Compared with a conventional low-voltage (LV) SRAM with ground-line assist circuits, the static random access memory device reduces the range of variation of the operating speed, increases the slowest operating speed, improves the reliability and the competitiveness of low voltage static random access memory, and expands the application range.

Below, the embodiments are described in detail in cooperation with the drawings to make easily understood the technical contents, characteristics and accomplishments of the present invention.

### BRIEF DESCRIPTION OF THE DRAWINGS

FIG. 1 is a diagram schematically illustrating a conventional 2×2 SRAM cell array with four standard 6T cells;

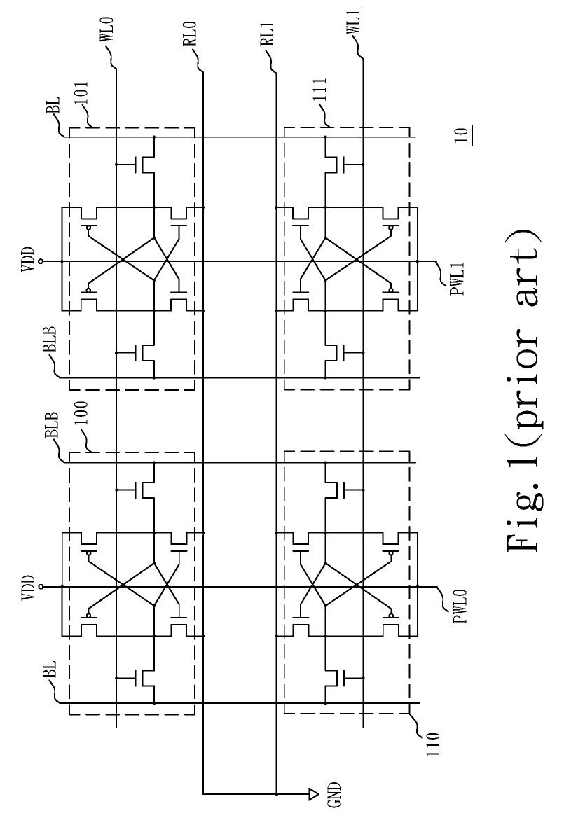

FIG. 2 is a diagram schematically illustrating conventional Generic-Split-Control (GSC) 6T cells;

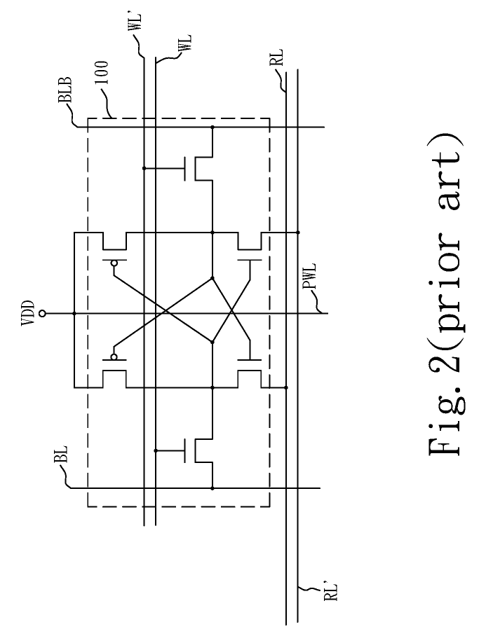

FIG. 3 is a diagram schematically illustrating a conventional 2x2 low-voltage (LV) SRAM cell array with four GSC 6T cells;

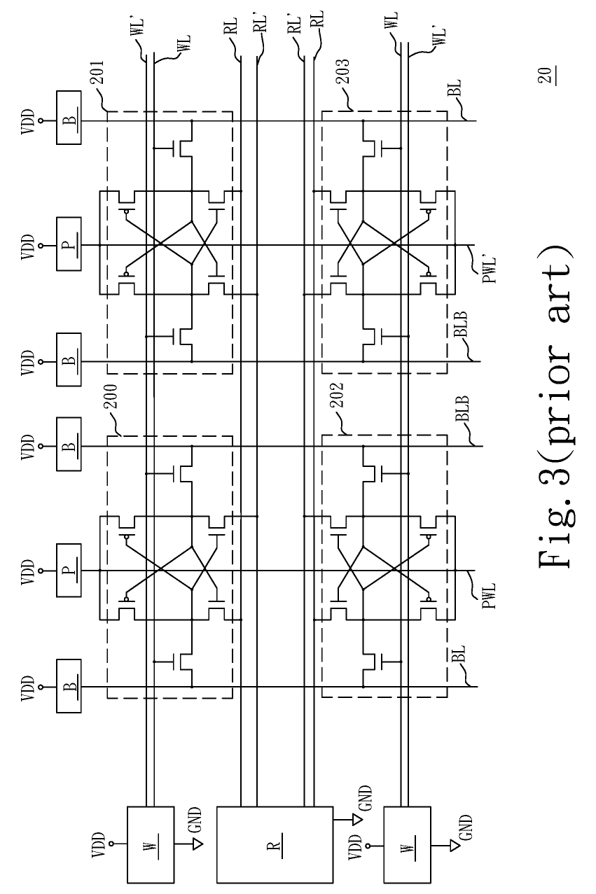

FIG. 4 is a diagram schematically illustrating the operation of a conventional 2x2 low-voltage (LV) SRAM cell array with four GSC 6T cells;

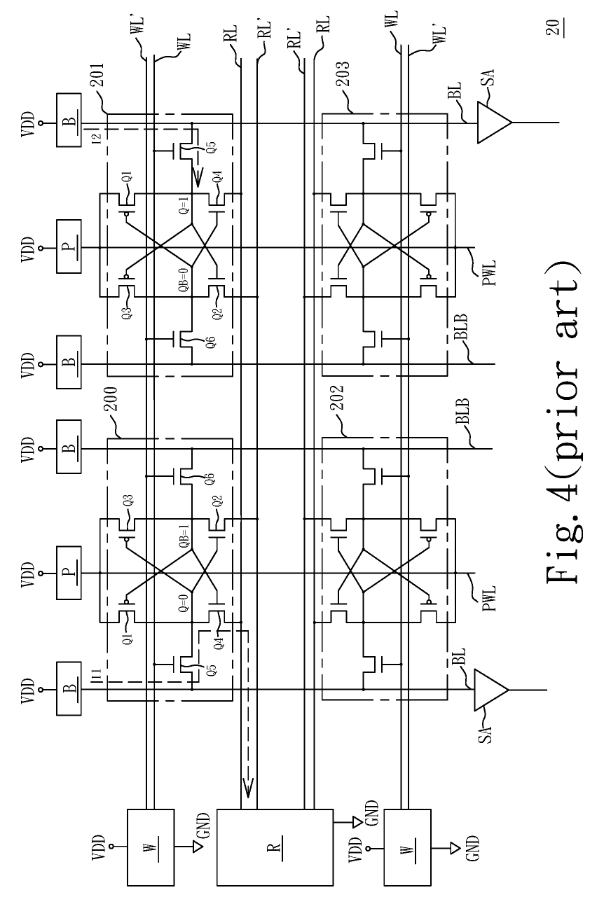

FIG. 5 is a diagram schematically illustrating a static random access memory device according to a first embodiment of the present invention;

FIG. 6 is a diagram schematically illustrating a static random access memory device according to a second embodiment of the present invention;

FIG. 7 is a diagram schematically illustrating a static random access memory device according to a third embodiment of the present invention; and

FIG. 8 is a diagram schematically illustrating a static random access memory device according to a fourth embodiment of the present invention.

### DETAILED DESCRIPTION OF THE INVENTION

Reference will now be made in detail to embodiments illustrated in the accompanying drawings. Wherever possible, the same reference numbers are used in the drawings and the description to refer to the same or like parts. In the drawings, the shape and thickness may be exaggerated for clarity and convenience. This description will be directed in particular to elements forming part of, or cooperating more directly with, methods and apparatus in accordance with the present disclosure. It is to be understood that elements not specifically shown or described may take various forms well known to those skilled in the art. Many alternatives and modifications will be apparent to those skilled in the art, once informed by the present disclosure.

When an element is referred to as being “on” another element, it can be directly on the other element or intervening elements may be present therebetween. In contrast, when an element is referred to as being “directly on” another element, there are no intervening elements present. As used herein, the term “and/or” includes any and all combinations of one or more of the associated listed items.

Reference throughout this specification to "one embodiment" or "an embodiment" means that a particular feature, structure, or characteristic described in connection with the embodiment is included in at least one embodiment. Thus, the appearances of the phrases "in one embodiment" or "in an embodiment" in various places throughout this specification are not necessarily all referring to the same embodiment.

The phrase “A/B” means A or B. For the purposes of the present invention, the phrase “A and/or B” means “(A), (B), or (A and B)”. For the purposes of the present invention, the phrase “at least one of A, B, and C” means “(A), (B), (C), (A and B), (A and C), (B and C), or (A, B and C)”. For the purposes of the present invention, the phrase “(A)B” means “(B) or (AB)”, that is, A is an optional element.

The terms chip, die, integrated circuit, monolithic device, semiconductor device, and microelectronic device are often used interchangeably in the microelectronics field. The present invention is applicable to all of the above as they are generally understood in the field.

In view of the challenges in the state of the art, the present invention relates to a static random access memory device, which arranges a power supply line that is parallel to bit lines and ground lines and perpendicular to word lines to avoid row-wise data dependency. Compared with a conventional low-voltage (LV) SRAM with ground-line assist circuits, the static random access memory device reduces the range of variation of the operating speed, increases the slowest operating speed, improves the reliability and the competitiveness of low voltage static random access memory, and expands the application range.

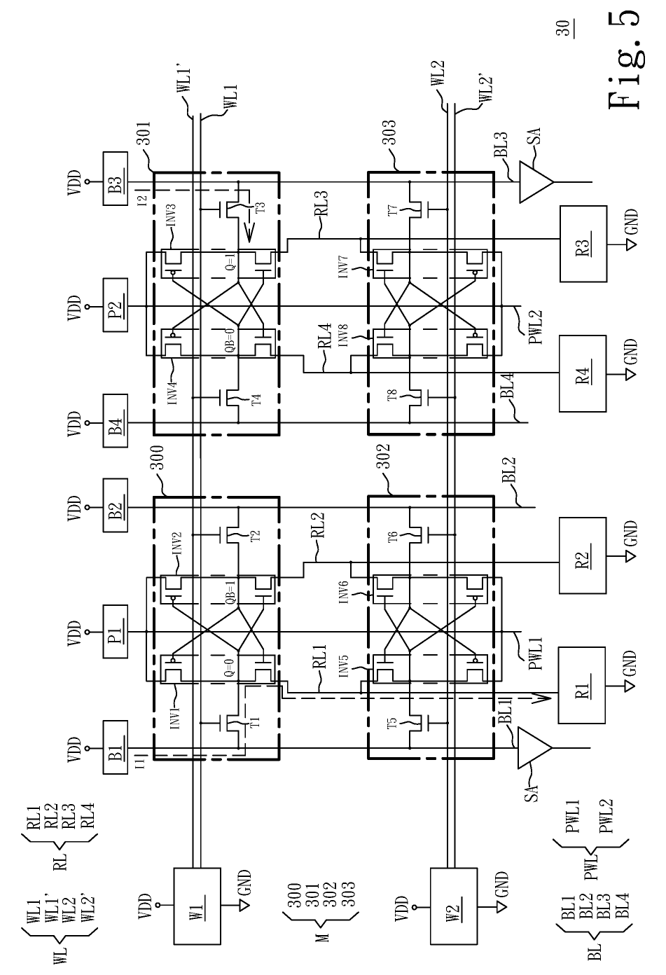

FIG. 5 is a diagram schematically illustrating a static random access memory device according to a first embodiment of the present invention. Referring to FIG. 5, the first embodiment of a static random access memory device 30 is introduced as follows. The static random access memory device 30 includes a plurality of word lines WL, a plurality of bit lines BL, a plurality of power supply lines PWL, a plurality of ground lines RL, and a plurality of static random access memory cells M. The static random access memory cell M may be, but not limited to, a Generic-Split-Control (GSC) 6T cell or a Dual-Split-Control 6T cell. The static random access memory cells M include at least a first static random access memory cell 300 and a second static random access memory cell 301. The word lines WL include at least one first word line WL1. The first embodiment exemplifies two first word lines WL1 and WL1’. The bit lines BL include a first bit line BL1, a second bit line BL2, a third bit line BL3, and a fourth bit line BL4. In FIG. 5, each of the first bit line BL1 and the third bit line BL3 is coupled to a sensing amplifier SA. Other sensing schemes, such as the differential sense amplifiers, can also be used along with the invented SRAM device. The power supply lines PWL include a first power supply line PWL1 and a second power supply line PWL2. The ground lines RL include a first ground line RL1, a second ground line RL2, a third ground line RL3, and a fourth ground line RL4. The power supply lines PWL run in a direction parallel to the bit lines BL and the ground lines RL but perpendicular to the word lines WL. The first static random access memory cell 300 includes a first inverter INV1, a second inverter INV2, a first pass transistor T1, and a second pass transistor T2. The first pass transistor T1 and the second pass transistor T2 may be, but not limited to, metal-oxide-semiconductor field effect transistors. The first inverter INV1 and the second inverter INV2 are cross-coupled and coupled to the first power supply line PWL1. The first inverter INV1 is coupled to the first ground line RL1. The second inverter INV2 is coupled to the second ground line RL2. The first pass transistor T1 is coupled to the first word line WL1, the first bit line BL1, the first power supply line PWL1, and the first inverter INV1. The second pass transistor INV2 is coupled to the first word line WL1’, the second bit line BL2, the first power supply line PWL1, and the second inverter INV2. The second static random access memory cell 301 includes a third inverter INV3, a fourth inverter INV4, a third pass transistor T3, and a fourth pass transistor T4. The third inverter INV3 and the fourth inverter INV4 may be, but not limited to, metal-oxide-semiconductor field effect transistors. The third pass transistor INV3 is coupled to the first word line WL1, the third bit line BL3, the second power supply line PWL2, and the third inverter INV3. The fourth pass transistor INV4 is coupled to the first word line WL1’, the fourth bit line BL4, the second power supply line PWL2, and the fourth inverter INV4. In some embodiments of the present invention, the first static random access memory cell 300 and the second static random access memory cell 301 may be arranged symmetric to each other.

The static random access memory cells M may further include a third static random access memory cell 302. The word lines WL may further include at least one second word line WL2. The first embodiment exemplifies two second word lines WL2 and WL2’. The third static random access memory cell 302 includes a fifth inverter INV5, a sixth inverter INV6, a fifth pass transistor T5, and a sixth pass transistor T6. The fifth pass transistor T5 and the sixth pass transistor T6 may be, but not limited to, metal-oxide-semiconductor field effect transistors. The fifth inverter INV5 and the sixth inverter INV6 are cross-coupled and coupled to the first power supply line PWL1. The fifth inverter INV5 is coupled to the first ground line RL1. The sixth inverter INV6 is coupled to the second ground line RL2. The fifth pass transistor T5 is coupled to the second word line WL2, the first bit line BL1, the first power supply line PWL1, and the fifth inverter INV5. The sixth pass transistor T6 is coupled to the second word line WL2’, the second bit line BL2, the first power supply line PWL1, and the sixth inverter INV6. In some embodiments of the present invention, the first static random access memory cell 300 and the third static random access memory cell 302 may be arranged symmetric to each other.

The static random access memory cells M may further include a fourth static random access memory cell 303. The fourth static random access memory cell 303 includes a seventh inverter INV7, an eighth inverter INV8, a seventh pass transistor T7, and an eighth pass transistor T8. The seventh pass transistor T7 and the eighth pass transistor T8 may be, but not limited to, metal-oxide-semiconductor field effect transistors. The seventh inverter INV7 and the eighth inverter INV8 are cross-coupled and coupled to the second power supply line PWL2. The seventh inverter INV7 is coupled to the third ground line RL3. The eighth inverter INV8 is coupled to the fourth ground line RL4. The seventh pass transistor T7 is coupled to the second word line WL2, the third bit line BL3, the second power supply line PWL2, and the seventh inverter INV7. The eighth pass transistor T8 is coupled to the second word line WL2’, the fourth bit line BL4, the second power supply line PWL2, and the eighth inverter INV8. In some embodiments of the present invention, the fourth static random access memory cell 303 and the third static random access memory cell 302 are arranged symmetric to each other, and the fourth static random access memory cell 303 and the second static random access memory cell 301 are arranged symmetric to each other.

The static random access memory device 30 may further include a first word-line assist circuit W1, a second word-line assist circuit W2, a first bit-line assist circuit B1, a second bit-line assist circuit B2, a first power-supply assist circuit P1, a first ground-line assist circuit R1 a second ground-line assist circuit R2, a third bit-line assist circuit B3 a fourth bit-line assist circuit B4, a second power-supply assist circuit P2, a third ground-line assist circuit R3, and a fourth ground-line assist circuit R4. The first word-line assist circuit W1 is coupled to the first word lines WL1 and WL1’ and coupled to a supply voltage VDD and a ground voltage GND. The second bit-line assist circuit W2 is coupled to the second word lines WL2 and WL2’ and coupled to the supply voltage VDD and the ground voltage GND. The first bit-line assist circuit B1 and the second bit-line assist circuit B2 are respectively coupled to first bit line BL1 and the second bit line BL2 and coupled to the supply voltage VDD. The first power-supply assist circuit P1 is coupled to the first power supply line PWL1 and coupled to the supply voltage VDD. The first ground-line assist circuit R1 and the second ground-line assist circuit R2 are respectively coupled to the first ground line RL1 and the second ground line RL2 and coupled to the ground voltage GND. The third bit-line assist circuit B3 and the fourth bit-line assist circuit B4 are respectively coupled to the third bit line BL3 and the fourth bit line BL4 and coupled to the supply voltage VDD. The second power-supply assist circuit P2 is coupled to the second power supply line PWL2 and coupled to the supply voltage VDD. The third ground-line assist circuit R3 and the fourth ground-line assist circuit R4 are respectively coupled to the third ground line RL3 and the fourth ground line RL4 and coupled to the supply voltage VDD.

When the first static random access memory cell 300 and the second static random access memory cell 301 perform a read operation, the storage nodes Q and QB of the first static random access memory cell 300 may respectively store data “0” and “1”, and storage nodes QB and Q of the second static random access memory cell 301 may respectively store data “0” and “1”. In the read operation, the NMOSFET of the first inverter INV1, the PMOSFET of the second inverter INV2, the first pass transistor T1, the third pass transistor T3, the PMOSFET of the third inverter INV3, and the NMOSFET of the fourth inverter INV4 are all turned on. The P MOSFET of the first inverter INV1, the NMOSFET of the second inverter INV2, the second pass transistor T2, the fourth pass transistor T4, the NMOSFET of the third inverter INV3, the PMOSFET of the fourth inverter INV4, the fifth pass transistor T5, the sixth pass transistor T6, the seventh pass transistor T7 and the eighth pass transistor T8 are all turned off. As a result, a first current I1 generated by the first bit-line assist circuit B1 sequentially flows through the first pass transistor T1 and the NMOSFET of the first inverter INV1 and finally flows to the first ground-line assist circuit R1. A second current I2 generated by the third bit-line assist circuit B3 stops at the NMOSFET of the third inverter INV3 when flowing through the third pass transistor T3. Thus, the invention improves the word-line-wise data dependency remarkably.

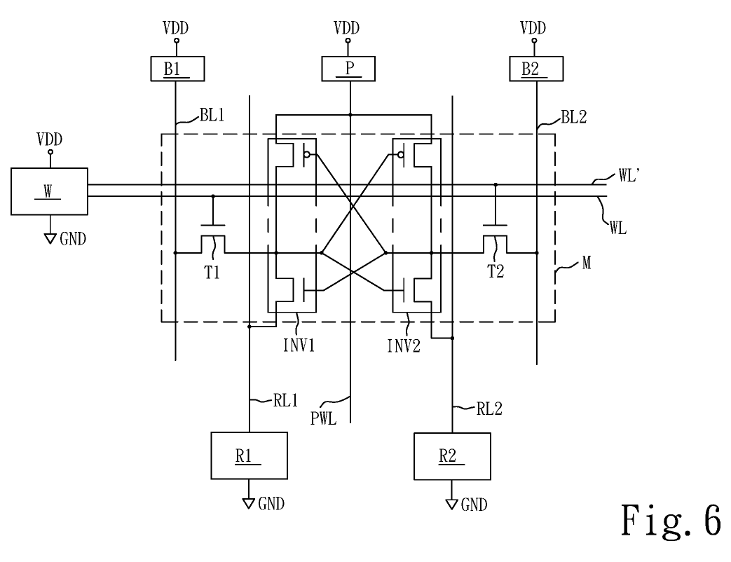

FIG. 6 is a diagram schematically illustrating a static random access memory device according to a second embodiment of the present invention. Referring to FIG. 6, the second embodiment of the static random access memory device is introduced as follows. The static random access memory device includes at least one word line WL, a first bit line BL1, a second bit line BL2, a power supply line PWL, a first ground line RL1, a second ground line RL2, and a static random access memory cell M. The second embodiment exemplifies two word lines WL and WL’. The power supply line PWL runs in a direction parallel to the first bit line BL1, the second bit line BL2, the first ground line RL1, and the second ground line RL2. The power supply line PWL runs in a direction perpendicular to the word lines WL and WL’. The static random access memory cell M includes a first inverter INV1, a second inverter INV2, a first pass transistor T1, and a second pass transistor T2. The first pass transistor T1 and the second pass transistor T2 may be, but not limited to, metal-oxide-semiconductor field effect transistors. The first inverter INV1 and the second inverter INV2 are cross-coupled and coupled to the power supply line PWL. The first inverter INV1 is coupled to the first ground line RL1. The second inverter INV2 is coupled to the second ground line RL2. The first pass transistor T1 is coupled to the word line WL, the first bit line BL1, the power supply line PWL, and the first inverter INV1. The second pass transistor T2 is coupled to the word line WL’, the second bit line BL2, the power supply line PWL, and the second inverter INV2. Since the power supply line PWL runs in a direction parallel to the first bit line BL1, the second bit line BL2, the first ground line RL1, and the second ground line RL2 but perpendicular to the word lines WL and WL’, the static random access memory device can improves the word-line-wise data dependency remarkably.

The static random access memory device may further include a word-line assist circuit W, a first bit-line assist circuit B1, a second bit-line assist circuit B2, a power-supply assist circuit P, a first ground-line assist circuit R1, and a second ground-line assist circuit R2. The word-line assist circuit W is coupled to the word lines WL and WL’ and coupled to a supply voltage VDD and a ground voltage GND. The first bit-line assist circuit B1 and the second bit-line assist circuit B2 are respectively coupled to the first bit line BL1 and the second bit line BL2 and coupled to the supply voltage VDD. The power-supply assist circuit P is coupled to the power supply line PWL and coupled to the supply voltage VDD. The first ground-line assist circuit R1 and the second ground-line assist circuit R1 are respectively coupled to the first ground line RL1 and the second ground line RL2 and coupled to the ground voltage GND.

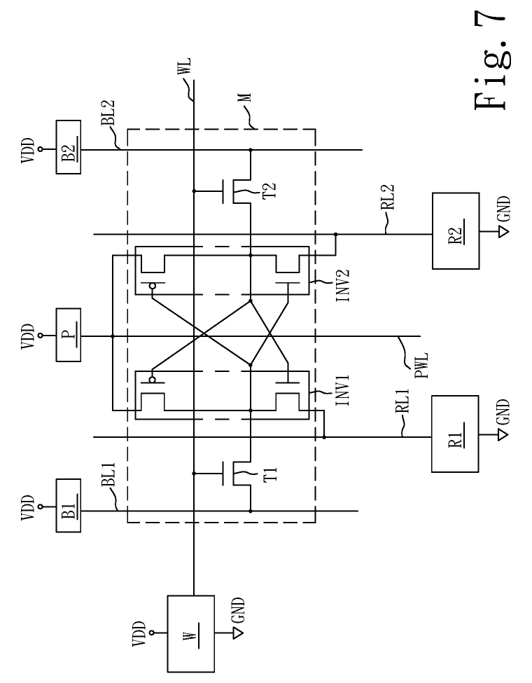

FIG. 7 is a diagram schematically illustrating a static random access memory device according to a third embodiment of the present invention. Referring to FIG. 7, the third embodiment of the static random access memory device is introduced as follows. The third embodiment is different from the second embodiment in the number of the word lines. The third embodiment exemplifies one word line WL coupled to the first pass transistor T1 and the second pass transistor T2. The other features of the third embodiment are the same as those of the second embodiment so they will not be reiterated.

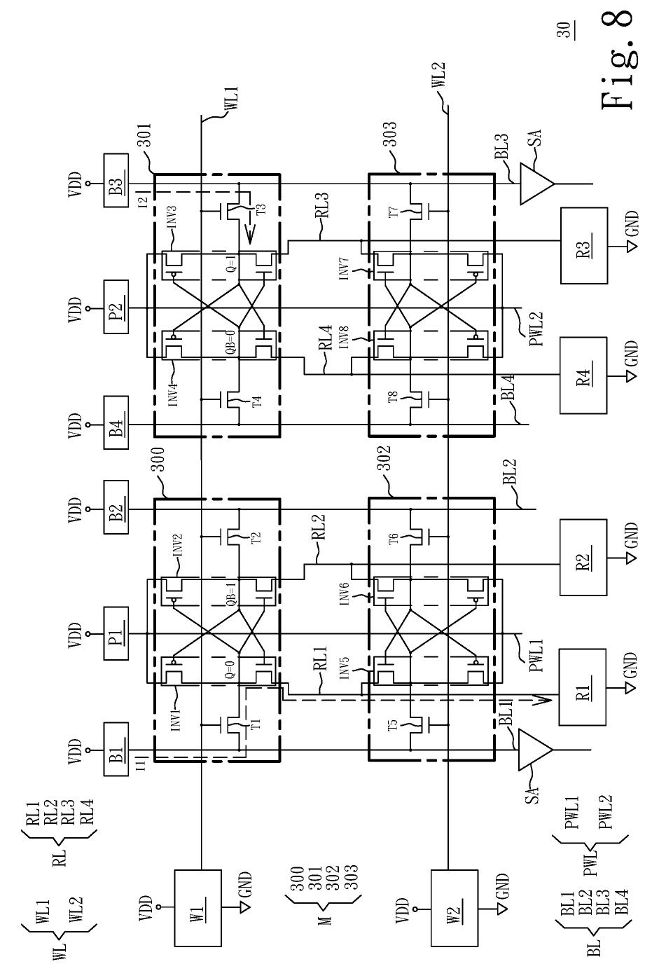

FIG. 8 is a diagram schematically illustrating a static random access memory device according to a fourth embodiment of the present invention. Referring to FIG. 8, the fourth embodiment of the static random access memory device is introduced as follows. The fourth embodiment is different from the first embodiment in the numbers of the first word lines and the second word lines. The fourth embodiment exemplifies one first word line WL1 and one second word line WL2. The first word line WL1 is coupled to the first pass transistor T1, the second pass transistor T2, the third pass transistor T3, and the fourth pass transistor T4. The second word line WL2 is coupled to the fifth pass transistor T5, the sixth pass transistor T6, the seventh pass transistor T7, and the eighth pass transistor T8. The other features of the fourth embodiment are the same as those of the first embodiment so they will not be reiterated.

According to the embodiments provided above, the static random access memory device arranges the power supply line that is parallel to the bit lines and the ground lines and perpendicular to the word lines to avoid row-wise data dependency. Compared with a conventional low-voltage (LV) SRAM with ground-line assist circuits, the static random access memory device reduces the range of variation of the operating speed, increases the slowest operating speed, improves the reliability and the competitiveness of low voltage static random access memory, and expands the application range.

The embodiments described above are only to exemplify the present invention but not to limit the scope of the present invention. Therefore, any equivalent modification or variation according to the shapes, structures, features, or spirit disclosed by the present invention is to be also included within the scope of the present invention.

What is claimed is:

1. A static random access memory device comprising:
at least one word line;
a first bit line and a second bit line;
a power supply line;
a first ground line and a second ground line, wherein the power supply line runs in a direction parallel to the first bit line, the second bit line, the first ground line, and the second ground line, and the power supply line runs in a direction perpendicular to the at least one word line; and
a static random access memory cell including:
a first inverter and a second inverter cross-coupled and coupled to the power supply line, wherein the first inverter is coupled to the first ground line, and the second inverter is coupled to the second ground line;
a first pass transistor coupled to the at least one word line, the first bit line, the power supply line, and the first inverter; and
a second pass transistor coupled to the at least one word line, the second bit line, the power supply line, and the second inverter.

2. The static random access memory device of claim 1, further comprising:
a word-line assist circuit coupled to the at least one word line;
a first bit-line assist circuit and a second bit-line assist circuit respectively coupled to the first bit line and the second bit line;
a power-supply assist circuit coupled to the power supply line; and
a first ground-line assist circuit and a second ground-line assist circuit respectively coupled to the first ground line and the second ground line.

3. The static random access memory device of claim 2, wherein the at least one word line includes two word lines that are respectively coupled to the first pass transistor and the second pass transistor.

4. The static random access memory device of claim 1, wherein the first pass transistor and the second pass transistor are metal-oxide-semiconductor field effect transistors.

5. A static random access memory device comprising:
a plurality of word lines including at least one first word line;
a plurality of bit lines including a first bit line, a second bit line, a third bit line, and a fourth bit line;
a plurality of power supply lines including a first power supply line and a second power supply line;
a plurality of ground lines including a first ground line, a second ground line, a third ground line, and a fourth ground line, wherein the plurality of power supply lines run in a direction parallel to the plurality of bit lines and the plurality of ground lines but perpendicular to the plurality of word lines; and
a plurality of static random access memory cells including a first static random access memory cell and a second static random access memory cell;
wherein the first static random access memory cell including:
a first inverter and a second inverter cross-coupled and coupled to the first power supply line, wherein the first inverter is coupled to the first ground line, and the second inverter is coupled to the second ground line;
a first pass transistor coupled to the at least one first word line, the first bit line, the first power supply line, and the first inverter; and
a second pass transistor coupled to the at least one first word line, the second bit line, the first power supply line, and the second inverter; and
wherein the second static random access memory cell including:
a third inverter and a fourth inverter cross-coupled and coupled to the second power supply line, wherein the third inverter is coupled to the third ground line, and the fourth inverter is coupled to the fourth ground line;
a third pass transistor coupled to the at least one first word line, the third bit line, the second power supply line, and the third inverter; and
a fourth pass transistor coupled to the at least one first word line, the fourth bit line, the second power supply line, and the fourth inverter.

6. The static random access memory device of claim 5, wherein the first static random access memory cell and the second static random access memory cell are arranged symmetric to each other.

7. The static random access memory device of claim 5, wherein the plurality of static random access memory cells further includes a third static random access memory cell, the plurality of word lines further includes at least one second word line, and the third static random access memory cell includes:
a fifth inverter and a sixth inverter cross-coupled and coupled to the first power supply line, wherein the fifth inverter is coupled to the first ground line, and the sixth inverter is coupled to the second ground line;
a fifth pass transistor coupled to the at least one second word line, the first bit line, the first power supply line, and the fifth inverter; and
a sixth pass transistor coupled to the at least one second word line, the second bit line, the first power supply line, and the sixth inverter.

8. The static random access memory device of claim 7, wherein the first static random access memory cell and the third static random access memory cell are arranged symmetric to each other.

9. The static random access memory device of claim 7, wherein the plurality of static random access memory cells further includes a fourth static random access memory cell, and the fourth static random access memory cell includes:
a seventh inverter and an eighth inverter cross-coupled and coupled to the second power supply line, wherein the seventh inverter is coupled to the third ground line, and the eighth inverter is coupled to the fourth ground line;
a seventh pass transistor coupled to the at least one second word line, the third bit line, the second power supply line, and the seventh inverter; and
an eighth pass transistor coupled to the at least one second word line, the fourth bit line, the second power supply line, and the eighth inverter.

10. The static random access memory device of claim 9, wherein the first pass transistor, the second pass transistor, the third pass transistor, the fourth pass transistor, the fifth pass transistor, the sixth pass transistor, the seventh pass transistor, and the eighth pass transistor are metal-oxide-semiconductor field effect transistors.

11. The static random access memory device of claim 9, wherein the fourth static random access memory cell and the third static random access memory cell are arranged symmetric to each other, and the fourth static random access memory cell and the second static random access memory cell are arranged symmetric to each other.

12. The static random access memory device of claim 9, wherein the at least one second word line includes two second word lines that are respectively coupled to the fifth pass transistor and the sixth pass transistor and respectively coupled to the seventh pass transistor and the eighth pass transistor.

13. The static random access memory device of claim 9, further comprising:
a first word-line assist circuit coupled to the at least one first word line;
a first bit-line assist circuit and a second bit-line assist circuit respectively coupled to first bit line and the second bit line;
a first power-supply assist circuit coupled to the first power supply line;
a first ground-line assist circuit and a second ground-line assist circuit respectively coupled to the first ground line and the second ground line;
a third bit-line assist circuit and a fourth bit-line assist circuit respectively coupled to the third bit line and the fourth bit line;
a second power-supply assist circuit coupled to the second power supply line; and
a third ground-line assist circuit and a fourth ground-line assist circuit respectively coupled to the third ground line and the fourth ground line.

14. The static random access memory device of claim 13, further comprising a second word-line assist circuit coupled to the at least one second word line.

15. The static random access memory device of claim 5, wherein the at least one first word line includes two first word lines that are respectively coupled to the first pass transistor and the second pass transistor and respectively coupled to the third pass transistor and the fourth pass transistor.
